(19) United States
(12) Patent Application Publication
(10) Pub. No.: US 2005/0276088 A1
(43) Pub. Date: Dec. 15, 2005

(54) Liquid crystal display device and method for driving the same

(75) Inventors: Seung-Hwan Moon, Yongin-si (KR); Sang-Soo Kim, Seoul (KR); Jae-Hyoung Park, Yongin-si (KR)

Correspondence Address: F. CHAU & ASSOCIATES, LLC, 130 WOODBURY ROAD, WOODBURY, NY, 11797, US

(73) Assignee: Samsung Electronics Co., LTD., Suwon-si (KR)

(21) Appl. No.: 11/147,514

(22) Filed: Jun. 8, 2005

(30) Foreign Application Priority Data
Jun. 9, 2004 (KR) 10-2004-0042302
Apr. 21, 2005 (KR) 10-2005-0033249

(51) Int. Cl. G11C 5/06

(52) U.S. Cl. 365/63

(57) ABSTRACT

A liquid crystal display device (LCD) includes a liquid crystal panel having a plurality of gate lines and a plurality of data lines arranged in column and row directions, respectively, and intersecting each other, a plurality of switching elements connected to the plurality of gate lines and the plurality of data lines, and a plurality of pixels connected to the plurality of switching elements, a gate driver for supplying a gate signal to the gate lines, a timing controller for receiving an external image signal and producing a first data signal and a second data signal having different gamma constants, and a data driver for supplying gray voltages corresponding to the first and second data signals produced from the timing controller to a first pixel group of the plurality of pixels and a second pixel group of the plurality of pixels via the data lines.

This application claims priority to Korean Patent Application Nos. 10-2004-0042302 and 10-2005-0033249 filed on Jun. 9, 2004 and Apr. 21, 2005, respectively, in the Korean Intellectual Property Office, the disclosures of which are incorporated by reference herein in their entireties.

### BACKGROUND OF THE INVENTION

1. Field of the Invention

The present disclosure relates to a liquid crystal display device (LCD) and a method for driving the same, and more particularly, to an LCD having improved visibility, wherein a difference in the gamma characteristic between front and lateral views is reduced, and a method for driving the same.

2. Description of Related Art

Demand for large-screen televisions has prompted the development of flat-panel display devices, such as liquid crystal displays (LCDs), plasma display panels (PDPs), or organic electroluminescent displays (OELDs), which are replacing conventional cathode ray tubes (CRTs). In particular, LCDs, which are compact and light, have been the focus of development efforts.

LCDs include an upper panel with a common electrode and a color filter, and a lower panel with a thin film transistor and a pixel electrode. A liquid crystal material having a dielectric anisotropy is injected between the upper panel and the lower panel. Light transmission through the panels is controlled by varying strengths of the electric fields applied to the upper and lower panels, thereby controlling an orientation of the liquid crystal material and displaying a desired image.

Thin film transistor liquid crystal displays (TFT LCD), which use thin film transistors as switching elements, are the mainstream technology in the LCD industry.

In a vertical alignment (VA) mode LCDs, in which longer axes of liquid crystal (LC) molecules are arranged perpendicularly to the upper and lower panels or substrates in a state in which an electric field is not applied thereto, have gained popularity because VA mode LCDs have a high contrast ratio and a wide viewing angle. The VA mode LCDs, as shown in FIG. 1, exhibit different gamma characteristics between the front and lateral views. The front and lateral views correspond to an on-axis gamma characteristic and an off-axis (upward, right, or diagonal) gamma characteristic. In VA mode LCDs these characteristics are different from each other, which results in poor lateral visibility. To improve lateral visibility, a plurality of subpixels may be formed in each pixel and a coupling capacitor may be formed between each of the plurality of subpixels to apply a gray voltage to one subpixel, by which the gray voltage is also applied to the other subpixels, which is referred to as a half-tone gray method.

Such a VA mode LCD includes a separate liquid crystal panel having a plurality of pixels each having multiple subpixels, which unavoidably reduces an aperture ratio, resulting in a reduction in the overall brightness of the liquid crystal panel. Particularly, when the liquid crystal panel is formed of an organic insulating layer, it is not possible to form a coupling capacitor having a large capacitance, and this makes it difficult to improve the visibility.

### SUMMARY OF THE INVENTION

According to an embodiment of the present disclosure, a liquid crystal display device (LCD) includes a liquid crystal panel having a plurality of gate lines and a plurality of data lines arranged in column and row directions, respectively, and intersecting each other. The liquid crystal panel includes a plurality of switching elements connected to the plurality of gate lines and the plurality of data lines, and a plurality of pixels connected to the plurality of switching elements. The LCD further comprises a gate driver for supplying a gate signal to the gate lines, a timing controller for receiving an external image signal and producing a first data signal and a second data signal having different gamma constants, and a data driver for supplying gray voltages corresponding to the first and second data signals produced from the timing controller to a first pixel group of the plurality of pixels and a second pixel group of the plurality of pixels via the data lines.

According to an embodiment of the present disclosure, a liquid crystal display device (LCD) includes a liquid crystal panel having a plurality of gate lines and a plurality of data lines arranged in column and row directions, respectively, and intersecting each other, a plurality of switching elements connected to the plurality of gate lines and the plurality of data lines, and a plurality of pixels connected to the plurality of switching elements. The LCD further comprises a gate driver for supplying a gate signal to the gate lines, a timing controller for receiving an external image signal and producing a first data signal and a second data signal selectively having different gamma constants or the same gamma constant, and a data driver for supplying gray voltages corresponding to the first and second data signals produced by the timing controller to a first pixel group of the plurality of pixels and a second pixel group of the plurality of pixels via the data lines.

According to an embodiment of the present disclosure, a method for driving a liquid crystal display device (LCD) comprising a liquid crystal panel having a plurality of gate lines and a plurality of data lines arranged in column and row directions, respectively, and intersecting each other, a plurality of switching elements connected to the plurality of gate lines and the plurality of data lines, and a plurality of pixels connected to the plurality of switching elements includes providing gate signals to the gate lines, receiving an external image signal and producing a first data signal and a second data signal corresponding to different gamma constants, and providing gray voltages corresponding to the first data signal and the second data signal to a first pixel group of the plurality of pixels and a second pixel group of the plurality of pixels through the data lines, respectively.

According to an embodiment of the present disclosure, a method for driving a liquid crystal display device (LCD) comprising a liquid crystal panel having a plurality of gate lines and a plurality of data lines arranged in column and row directions, respectively, and intersecting each other, a plurality of switching elements connected to the plurality of gate lines and the plurality of data lines, and a plurality of pixels connected to the plurality of switching elements includes providing gate signals to the gate lines, receiving an external image signal and producing a first data signal and a second data signal having the same or different gamma constants, and providing gray voltages corresponding to the first data signal and the second data signal to a first pixel group of the plurality of pixels and a second pixel group of the plurality of pixels through the data lines, respectively.

### BRIEF DESCRIPTION OF THE DRAWINGS

The present disclosure will become more apparent by describing in detail preferred embodiments thereof with reference to the attached drawings in which:

FIG. 1 is a gamma curve of a conventional VA mode LCD;

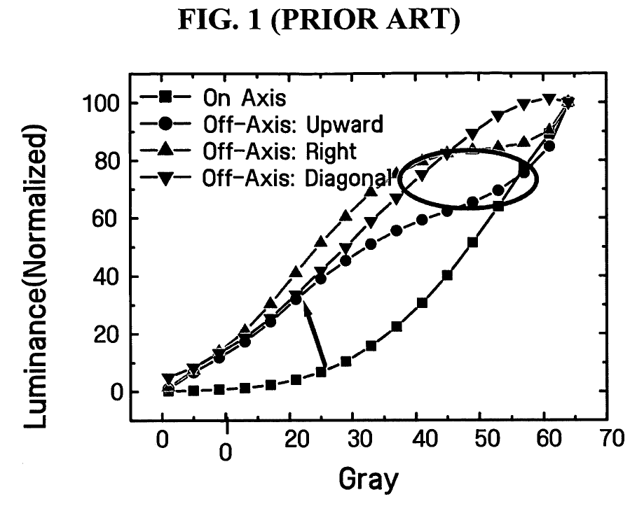

FIG. 2A is a block diagram of an LCD of an embodiment of the present disclosure;

FIG. 2B is a block diagram of an LCD of another embodiment of the present disclosure;

FIG. 3A is a gamma curve for a front view of the LCD of an embodiment of the present disclosure;

FIG. 3B is a gamma curve for a lateral view of the LCD of an embodiment of the present disclosure;

FIG. 4 is a graph showing the relationship between a user s range of vision and the effective PPI (Pixels Per Inch) of the LCD;

FIGS. 5 and 6 show tables that illustrate that data signals having different gamma constants are applied to each pixel group of the LCD irrespective of frame;

FIGS. 7A through 8B illustrate liquid crystal panels to which data signals having different gamma constants are applied for each predetermined frame;

FIGS. 9A through 10B illustrate inversion driving signals according to an embodiment of the present disclosure;

FIGS. 11A and 11B are graphs showing the viewing angle dependency of chrominance in the conventional VA mode LCD and in the LCD according to an embodiment of the present disclosure, respectively; and

FIG. 12 is a block diagram of an LCD of another embodiment of the present disclosure.

### DETAILED DESCRIPTION OF PREFERRED EMBODIMENTS

The present disclosure may be understood more readily with reference to the following detailed description of preferred embodiments and the accompanying drawings. The present invention may be embodied in many different forms and should not be construed as being limited to embodiments set forth herein. Rather, these embodiments are provided so that this disclosure will be thorough and complete and will fully convey the concept of the invention to those skilled in the art. Like reference numerals refer to like elements throughout the specification.

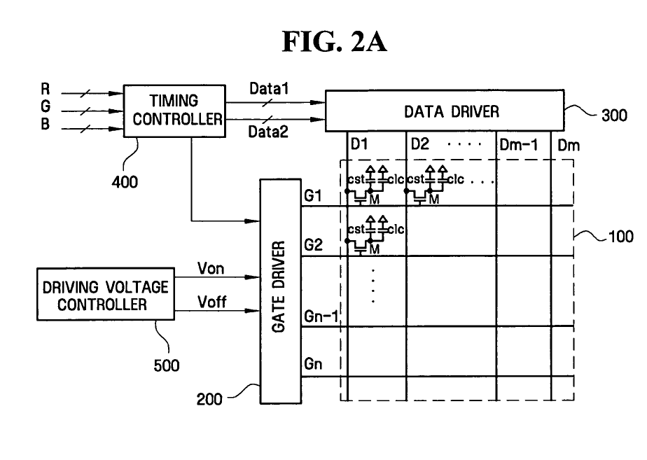

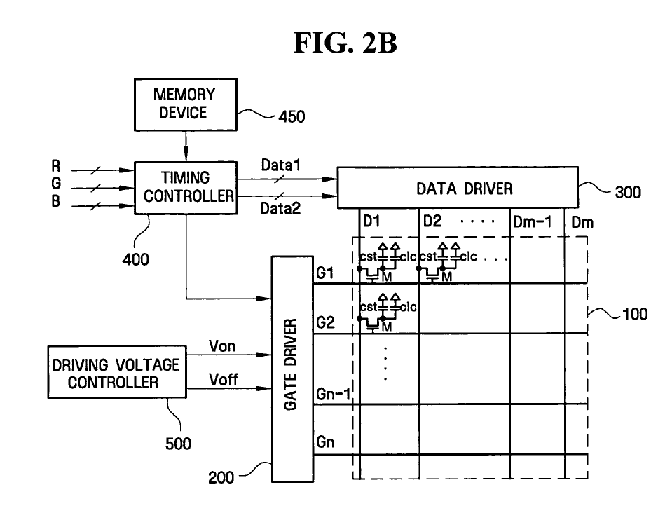

Referring to FIG. 2A, the LCD includes a liquid crystal panel 100, a gate driver 200, a data driver 300, and a timing controller 400.

The liquid crystal panel 100 includes a plurality of gate lines G1 through Gn and a plurality of data lines D1 through Dm, arranged in row and column directions, respectively, and intersecting each other, switching elements M connected to the plurality of gate lines G1 through Gn and the plurality of data lines D1 through Dm, and a plurality of pixels connected to the plurality of switching elements M. The plurality of pixels may include a first pixel group and a second pixel group. The first pixel group and the second pixel group are alternately arranged to form a matrix pattern, and their arrangement may change as described in more detail hereafter. The first pixel group and the second pixel group, or one or the other, comprise one or three pixels. For example, in a case where one pixel is used as a basic unit of a matrix pattern of the first pixel group or the second pixel group, the first pixel group is a set of pixels in which the sum of the columns and rows in the matrix is an even number, and the second pixel group is a set of pixels in which the sum of columns and rows in the matrix is an odd number. Alternatively, the first pixel group may be a set of pixels in which the sum of columns and rows in the matrix is an odd number, and the second pixel group may be a set of pixels in which the sum of columns and rows in the matrix is an even number.

The respective pixels include switching elements M connected to the plurality of gate lines G1 through Gn and the plurality of data lines D1 through Dm, liquid crystal capacitors Clc connected to the switching elements M, and storage capacitors Cst.

The plurality of gate lines G1 through Gn arranged in the row direction transmit gate signals to the switching elements M, and the plurality of data lines D1 through Dm transmit gray voltages corresponding to data signals to the switching elements M. Each switching element M is a three-terminal element having a control terminal connected to one of the gate lines G1 through Gn, an input terminal connected to one of the data lines D1 through Dm, and output terminals connected to either the liquid crystal capacitors Clc or the storage capacitors Cst. Metal oxide semiconductor (MOS) transistors may be used as the switching elements M. In such MOS transistors, channel layers are formed using amorphous silicon or polycrystalline silicon to implement thin film transistors. A liquid crystal capacitor Clc may be connected between an output terminal of the respective switching element M and a common electrode (not shown), and a storage capacitor Cst may be independently wired between an output terminal of the respective switching element M and the common electrode, or may be connected between an output terminal of the respective switching element M and one of the gate lines G1 through Gn.

The gate driver 200 is connected to the plurality of gate lines G1 through Gn, and provides the plurality of gate lines G1 through Gn with gate signals. The gate signals comprise a combination of gate ON voltages Von and gate OFF voltages Voff supplied from a driving voltage generator 500. The data driver 300 is connected to the plurality of data lines D1 through Dm, and generates gray voltages to provide the plurality of data lines D1 through Dm with a first data signal Data1 and a second data signal Data2 produced by the timing controller 400.

The timing controller 400 receives R, G, B signals from an external graphics source (not shown) and sends the first data signal Data1 and the second data signal Data2 having different gamma constants to the data driver 300. Here, the first data signal Data1 is transmitted to pixels belonging to the first pixel group, and the second data signal Data2 is transmitted to pixels belonging to the second pixel group. In addition, the timing controller 400 generates a gate selection signal Gate CLK or CPV for controlling the output of gate ON/OFF signals Von/Voff, a vertical synchronization start signal STV, an output enable signal OE, and others and transmits them to the gate driver 200.

Hereinafter, a process of outputting the first data signal Data1 and the second data signal Data2 corresponding to different gamma constants from the timing controller 400 will be described in detail.

The timing controller 400 receives an external image signal for the first pixel group from the graphics source and outputs the first data signal Data1 to the data driver 300. The first data signal Data1 is obtained by modifying a gamma characteristic of the external image signal so that its gamma curve matches the gamma curve of a first gamma constant γ1. The timing controller 400 also receives an external image signal for the second pixel group from the graphics source and outputs the second data signal Data2 to the data driver 300. The second data signal Data2 is obtained by modifying a gamma characteristic of the external image signal so that its gamma curve matches the gamma curve of a second gamma constant γ2. Here, the first gamma constant γ1 and the second gamma constant γ2 are different, and correspond to the first data signal Data1 and the second data signal Data2, respectively. The first gamma constant γ1 and the second gamma constant ≡2 may be kept constant irrespective of predetermined periods. In addition, the first data signal Data1 is transmitted to pixels belonging to the first pixel group and the second data signal Data2 is transmitted to pixels belonging to the second pixel group.

Further, when outputting the first data signal and the second data signal corresponding to different gamma constants, the timing controller 400 may exchange the gamma constants to apply the same to the first data signal and the second data signal for each predetermined period. For example, in the first period, the timing controller 400 receives an external image signal for the first pixel group, modifies its gamma characteristic to match with the gamma curve of the first gamma constant γ1, and then outputs it as the first data signal Data1. In the same period, the timing controller 400 also receives an external image signal for the second pixel group whose gamma characteristic has been modified to match with the gamma curve of the second gamma constant γ2, and then outputs it as the second data signal, Data2. Thereafter, in the second period, the timing controller 400 receives an external image signal for the first pixel group and modifies its gamma characteristic to match with the gamma curve of the second gamma constant γ2 and then outputs it as the first data signal Data1, and the timing controller 400 also receives an external image signal for the second pixel group, modifies its gamma characteristic to match with the gamma curve of the first gamma constant γ1, and then outputs it as the second data signal Data2. Here, the first period and the second period may be the same, and may be, for example, 1 frame.

The timing controller 400 may output the first data signal Data1 and the second data signal Data2, which alternately have the first gamma constant γ1 and the second gamma constant γ2, using a look-up table (LUT) or a computational operation. The LUT may be stored in the memory of the timing controller 400, e.g., a nonvolatile memory device such as a ROM (Read Only Memory). In this case, a gamma constant can be adjusted without changing the configuration of the liquid crystal panel 100.

FIG. 2B is a block diagram of an LCD according to an embodiment of the present disclosure. As shown in FIG. 2B, a separate memory device 450 is connected to the timing controller 400, which stores the LUT. In this case, since the memory device 450 can be changed or replaced, a variety of LUTs can be used according to user requirements. In addition, when a new liquid crystal panel is used, the new liquid crystal panel can be adapted by using only optimal LUTs. Here, a variety of memory storage devices can be used as the memory device 450; for example, a ROM, an EEPROM (Electric Erasable and Programmable Read-Only Memory) or the like can be used.

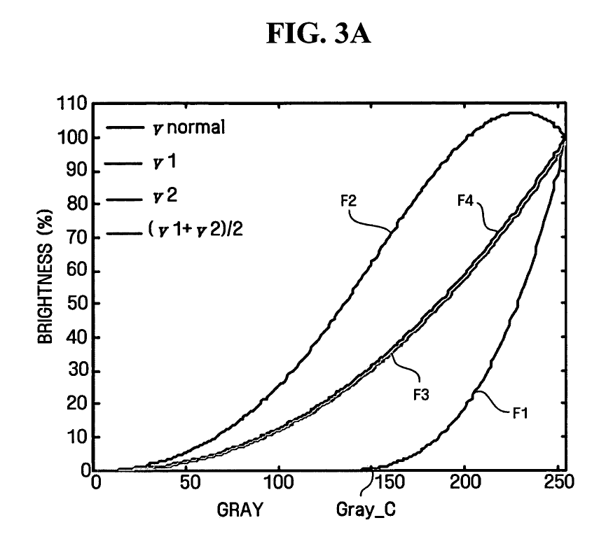

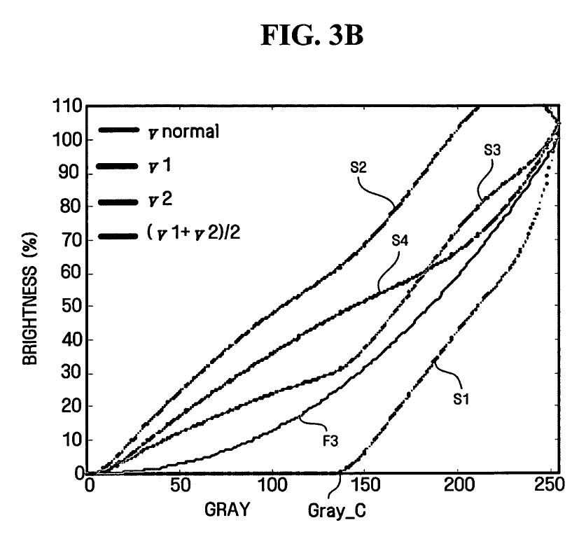

Front and lateral gamma characteristics of an LCD according to an embodiment of the present disclosure will now be described in more detail with reference to FIGS. 3A and 3B. FIG. 3A is a gamma curve for a front view of the LCD, and FIG. 3B is a gamma curve for a lateral view of the LCD. Although gamma characteristics have been explained by way of 256 gray levels in graphs shown in FIGS. 3A and 3B, the invention is not limited thereto and can be applied to LCDs using 64 gray levels, 1024 gray levels or others.

The following relationship is established between brightness and gray level of an LCD.
Normalized brightness=(Gray level/Maximum gray level)^{γ}
where γ indicates a gamma constant,
As such, the normalized brightness is proportional to the γ-th power of the gray level. Therefore, the gamma curves shown in FIGS. 3A and 3B indicate an exponential relationship between the brightness and gray level.

Referring to FIG. 3A, which shows the gamma curve for the front view, the gamma curve F4 shows the relationship between brightness and gray level using a gamma constant of, e.g., 2.2, 2.4 or 2.6; hereinafter, referred to as a normalized gamma constant (γnormal) for a general LCD. Referring to FIG. 3B, which shows the gamma curve for the lateral view, the gamma curve S4 shows the relationship between brightness and gray level using a normalized gamma constant. Comparing the gamma curves F4 and S4 shown in FIGS. 3A and 3B, it can be seen that the brightness greatly increases in the case of using the normalized gamma constant (γnormal) in intermediate gray levels when the LCD is viewed laterally. While a conventional LCD has good front visibility, the lateral brightness increases rapidly, resulting in degradation of visibility.

In FIGS. 3A and 3B, the gamma curves F1 and S1 use a first gamma constant γ1 for a front view and a lateral view, and the gamma curves F2 and S2 use a second gamma constant γ2 for a front view and a lateral view. The first gamma constant γ1 and the second gamma constant γ2 can be defined such that the gamma curve F3 indicating the average brightness of the gamma curves F1 and F2 becomes substantially similar to the gamma curve F4 using the normalized gamma constant γnormal. The gamma curve S3 indicates the average brightness of the gamma curve S1 and S2 for lateral views, and the brightness difference of the gamma curve S3 and F3 can be smaller than the brightness difference of the gamma curve S4 and F3.

A method for defining the first gamma constant γ1 and the second gamma constant γ2 will now be described in detail. When the second gamma constant γ2 is smaller than the first gamma constant γ1, as shown in FIGS. 3A and 3B, the gamma curves F1 and S1 are below the gamma curves F2 and S2. In the gamma curves F4 and S4 using the normalized gamma constant γnormal, there is a noticeable difference in the gamma curves for the front and lateral views at lower gray levels. To prevent lateral brightness from increasing at lower gray levels, the first gamma constant γ1 may be set to various values according to the gray level. That is, the first gamma constant γ1 is set to a higher value at a lower gray level and the brightness is about zero in this range.

Assuming that the maximum gray level where the brightness is about zero in the gamma curve F1 or S1 is a critical gray level Gray_C, the first gamma constant γ1 may vary on the basis of this critical gray level Gray_C. The first gamma constant γ1 preferably has a larger value in the first period than in the second period. Here, the first period is lower than the critical gray level Gray_C and the second period is greater than the critical gray level Gray_C. The first gamma constant γ1 can be greater than 3, provided it is not greater than the critical gray level Gray_C.

As described above, the first gamma constant γ1 and the second gamma constant γ2 are set such that the average of the brightness based on the first gamma constant γ1 and the brightness based on the second gamma constant γ2 becomes substantially similar to the brightness based on the normalized gamma constant normal, thereby minimizing a difference in the gamma characteristics between the front and lateral views. Therefore, a plurality of subpixels for each pixel are not needed.

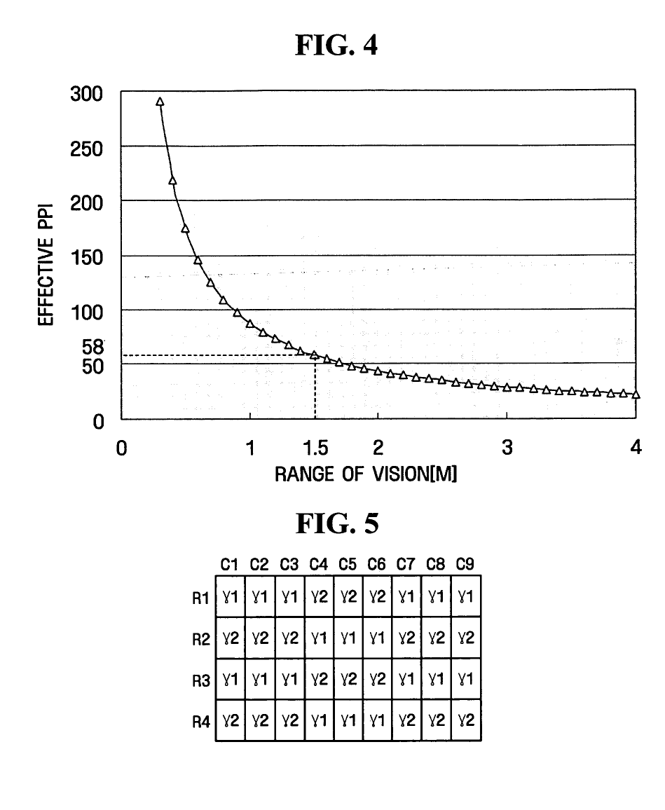

FIG. 4 is a graph showing the relationship between a user's range of vision and the effective PPI (Pixels Per Inch) of the LCD. Here, PPI is the resolution of the LCD; specifically, the number of pixels formed per inch. Generally, as an object is moved toward a viewer's eye, the object is seen more clearly because more information reaches the retina of the viewer's eye. The closest distance to which the eye can focus is referred to as the near point or the point of most distinct vision, and maximum resolution occurs at that point. For most people, the near point is about 30 cm, and the angular resolution at the near point is about 1/60° (0.0167°). The human eye has maximum resolution at the near point. The resolution of the eye deteriorates for objects closer or farther than the near point. For an object 1.5 m away from the eye, the angular resolution of the eye is 436 μm. A pixel pitch of 436 μm corresponds to an LCD resolution of about 58 PPI.

In a case where the timing controller 400 provides the first data signal Data1 and the second data signal Data2 corresponding to the first gamma constant γ1 and the second gamma constant γ2, respectively, irrespective of a predetermined frame, when the liquid crystal panel 100 displays data signals having different gamma constants by adjacent pixel groups, which cannot be perceived by the human eye in a high density LCD of about 58 PPI, an image with improved lateral visibility can be realized.

Embodiments of the present disclosure can be applied to any LCD. For high density LCDs, in addition to improving lateral visibility, image roughness can also be avoided by alternately changing the gamma constants of the data signals for each predetermined period. For instance, the timing controller 400 can send frames of the first data signal Data1 and the second data signal Data2 to the data driver 300. Odd-numbered frames of the first data signal Data1 have the first gamma constant γ1 and even-numbered frames have the second gamma constant γ2. Odd-numbered frames of the second data signal Data2 have the second gamma constant γ2 and even-numbered frames have the first gamma constant γ1. In such a manner, flicker or line patterns can be effectively suppressed and the contrast ratio can be improved. While the LCD according to an embodiment of the present disclosure has been described with frames having different gamma constants, it is not limited thereto and the period for changing the gamma constants can be changed in various manners. If the period is a plurality of frames, a flicker phenomenon or line pattern may occur. Thus, as long as such adverse phenomena can be prevented, the changing period of the gamma constant can be varied in various manners. For brevity, embodiments of the present disclosure will now be described using a data signal having frames with alternately different gamma constants.

In a conventional LCD, where a coupling capacitor is used to improve the lateral visibility between pixels and subpixels, since an organic insulating layer used as a dielectric material occupies a large area, the aperture ratio is reduced. By contrast, in an LCD according to an embodiment of the present disclosure, since no coupling capacitor is used, the aperture ratio can be increased. In addition, in an LCD according to an embodiment of the present disclosure, separate subpixels within a pixel are not needed, thereby enhancing the entire brightness of the liquid crystal panel 100, compensating for a variation in the gamma characteristics of the liquid crystal panel 100 according to the processing variation.

A frame can be represented by a two-dimensional plane X and Y. Here, X represents the horizontal axis and Y represents the vertical axis. A Z-axis represents time and Z values are in units of frames. Pixels are represented by X, Y and Z values. In this case, a duty rate is defined by fixing X and Y values and dividing the number of turned-on pixels while predetermined frames are repeated by the number of frames. For example, if a duty rate of a gray voltage level of a data signal is ½ at (1,1), then this pixel is turned on during one of the 2 frames. Accordingly, to represent a variety of gray voltage levels using a LCD, a frame rate control (FRC) type LCD can be used; in an FRC LCD the duty rates for the respective gray voltage levels are set and pixels are turned on or off according to these duty rates. In addition to applying data signals having different gamma constants, the pixels are also dithered, which contributes to producing a picture with improved lateral visibility.

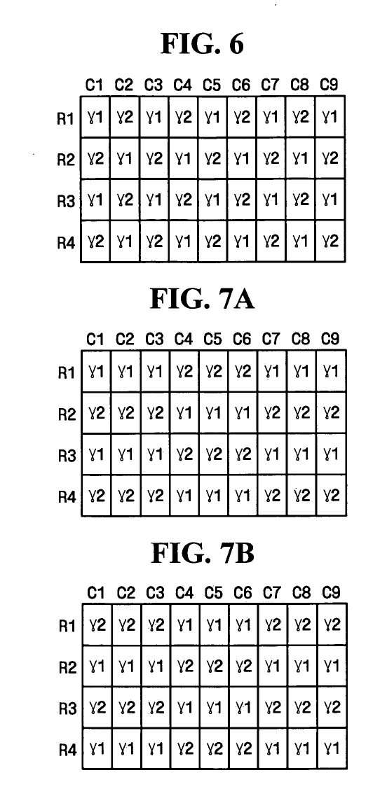

Data signals applied to pixel groups of a liquid crystal panel of an LCD according to an embodiment of the present disclosure will now be described with reference to FIGS. 5 through 8B.

FIGS. 5 and 6 show tables that illustrate that data signals having different gamma constants are applied to each pixel group of the LCD irrespective of frame.

In detail, FIG. 5 shows a first pixel group and a second pixel group alternately arranged in a matrix pattern and composed of R, G, and B pixels. As shown in FIG. 5, the first data signal Data1 having the first gamma constant γ1 is applied to the pixels of the first pixel group, and the second data signal Data2 having the second gamma constant γ2 is applied to the pixels of the second pixel group. Here, positions of the first pixel group and the second pixel group may be shifted.

FIG. 6 shows a first pixel group and a second pixel group each having one pixel as a basic unit alternately arranged in a matrix pattern. As shown in FIG. 6, the first pixel group is a set of pixels, in which the sum of columns and rows is an even number, and the second pixel group is a set of pixels, in which the sum of columns and rows is an odd number. The first data signal Data1 having the first gamma constant γ1 may be applied to the pixels belonging to the first pixel group (e.g., pixels of odd-numbered columns C1, C3, C5, C7 and C9 of the odd-numbered rows R1 and R3 and pixels of odd-numbered columns C2, C4, C6 and C8 of even-numbered rows R2 and R4). In addition, the second data signal Data2 having the second gamma constant γ2 may be applied to the pixels belonging to the second pixel group (e.g., pixels of even-numbered columns C2, C4, C6 and C8 of the odd-numbered rows R1 and R3 and pixels of odd-numbered columns C1, C3, C5, C7 and C9 of even-numbered rows R2 and R4). Here, positions of the first pixel group and the second pixel group may be shifted.

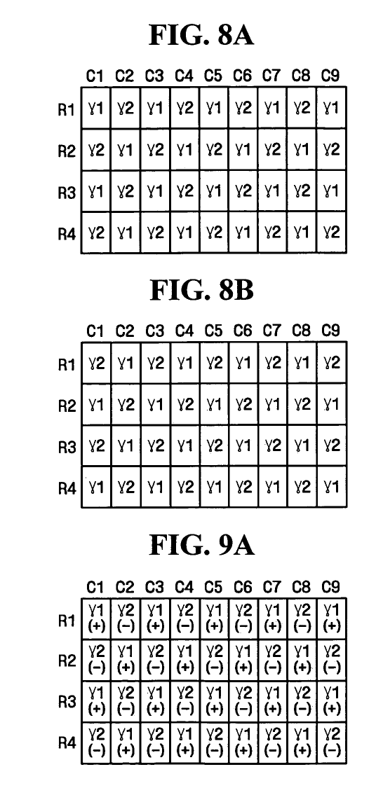

FIGS. 7A through 8B illustrate liquid crystal panels to which data signals having different gamma constants are applied for each predetermined frame;

In detail, FIGS. 7A and 7B show liquid crystal panels to which data signals are applied for a period of 1 frame; FIG. 7A shows a data signal applied to an odd-numbered frame and FIG. 7B shows a data signal applied to an even-numbered frame. The first and second pixel groups are alternately arranged to form a matrix pattern and are composed of R, G, and B pixels.

As shown in FIG. 7A, in the odd-numbered frame, the first data signal Data1 is applied to the pixel belonging to the first pixel group, and the second data signal Data2 is applied to the pixel belonging to the second pixel group.

In the even-numbered frame, as shown in FIG. 7B, the second data signal Data2 corresponding to the second gamma constant γ2 is applied to the pixel belonging to the first pixel group and the first data signal Data1 corresponding to the first gamma constant γ1 is applied to the pixel belonging to the second pixel group.

Here, the data signals can be switched.

FIGS. 8A and 8B show liquid crystal panels to which data signals are applied for a period of 1 frame; FIG. 8A shows a data signal applied to an even-numbered frame and FIG. 8B shows a data signal applied to an odd-numbered frame.

Here, the first and second pixel groups are alternately arranged to form a matrix pattern and are composed of one pixel.

In the odd-numbered frame, as shown in FIG. 8A, the first data signal Data1 is applied to the pixels belonging to the first pixel group (e.g., pixels of odd-numbered columns C1, C3, C5, C7 and C9 of the odd-numbered rows R1 and R3 and pixels of even-numbered columns C2, C4, C6 and C8 of even-numbered rows R2 and R4). In addition, the second data signal Data2 is applied to the pixels belonging to the second pixel group (e.g., pixels of even-numbered columns C2, C4, C6 and C8 of the odd-numbered rows R1 and R3 and pixels of odd-numbered columns C1, C3, C5, C7 and C9 of even-numbered rows R2 and R4).

In the even-numbered frame, as shown in FIG. 8B, the first data signal Data1 is applied to the pixels belonging to the first pixel group, that is, pixels of odd-numbered columns C1, C3, C5, C7 and C9 of the odd-numbered rows R1 and R3 and pixels' of even-numbered columns C2, C4, C6 and C8 of even-numbered rows R2 and R4. In addition, the second data signal Data2 2 is applied to the pixels belonging to the second pixel group, that is, pixels of odd-numbered columns C1, C3, C5, C7 and C9 of the even-numbered rows R2 and R4 and pixels of odd-numbered columns C1, C3, C5, C7 and C9 of even-numbered rows R2 and R4.

The data signal corresponding to the gamma constant shown in FIG. 8A is not necessarily applied to the odd-numbered frames, and the data signal corresponding to the gamma constant shown in FIG. 8B is not necessarily applied to the even-numbered frames. The data signal corresponding to the gamma constant shown in FIG. 8B may be applied to the odd-numbered frames, and the data signal corresponding to the gamma constant shown in FIG. 8A may be applied to the even-numbered frames.

While the period for changing gamma constants one frame, embodiments of the present disclosure are not limited thereto and the period can be changed in various manners as long as flicker or line patterns are prevented.

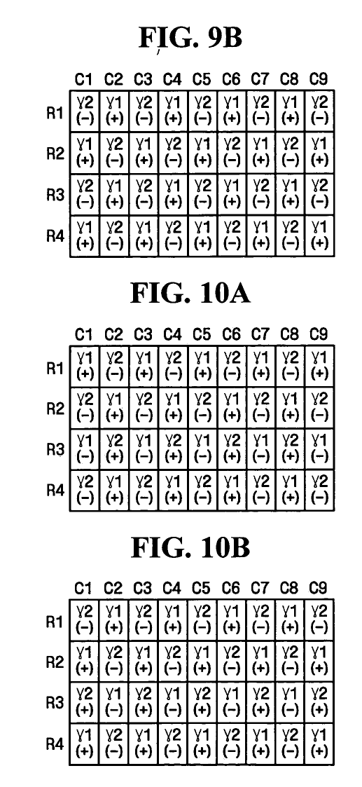

Inversion driving of data signals adopted in an LCD according to an embodiment of the present disclosure will now be described with reference to FIGS. 9A through 10B. For brevity, inversion driving is described using the liquid crystal panel shown in FIGS. 8A and 8B. Embodiments of the present disclosure can be applied to various liquid crystal panels having the first pixel group and second pixel group arranged in various manners as described above.

FIGS. 9A and 9B illustrate dot inversion driving signals, and FIGS. 10A and 10B illustrate (1+2) dot inversion driving signals. In FIGS. 9A through 10B, (+) and (−) signs indicate polarities of the respective pixels.

The data signals applied to the respective pixels of an LCD according to an embodiment of the present disclosure are not limited to dot inversion driving signals or (1+2) dot inversion driving signals, and may take a variety of inversion driving forms. Preferably, the data signals are dot inversion driving signals since these signals suppress flicker and improving the contrast ratio.

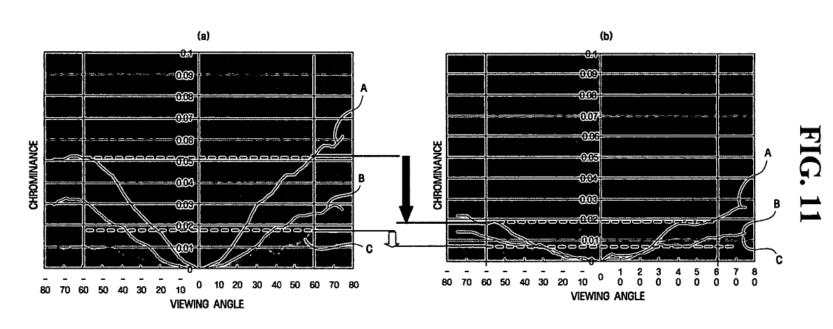

FIGS. 11A and 11B are graphs showing variations in color coordinates (hereinafter referred to as chrominance) with respect to changes in the viewing angle according to an embodiment of the present disclosure; FIG. 11A shows the viewing angle dependency of chrominance in the conventional VA mode LCD, and FIG. 11B shows the viewing angle dependency of chrominance in an LCD according to an embodiment of the present disclosure. Here, curve A shows the chrominance of RGB colors having gray level (192, 128, 64), curve B shows the chrominance of RGB colors having gray level (64, 192, 128), and curve C shows the chrominance of RGB colors having gray level (217, 172, 144).

As shown in FIGS. 11A and 11B, in an LCD according to an embodiment of the present disclosure, a first data signal and a second data signal corresponding to different gamma constants are applied to first and second pixel groups alternately arranged in a matrix pattern, thereby considerably reducing lateral chrominance.

The above-described LCD is driven by the first data signal Data1 and the second data signal Data2, which have different gamma constants.

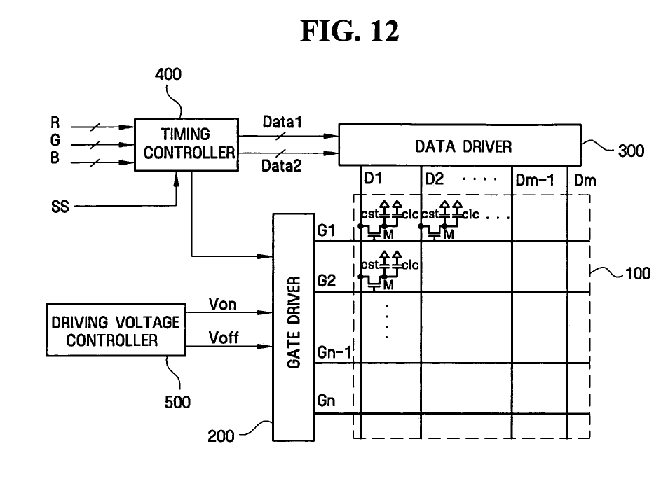

FIG. 12 is a block diagram of an LCD of an embodiment of the present disclosure. The picture quality of the LCD can be controlled by a user. That is, the picture quality of the LCD is controlled by making gamma constants of the first data signal Data1 and the second data signal Data2 the same or different.

When only front visibility is considered (hereinafter referred to as an ordinary mode), a selection signal SS, making the first data signal Data1 and the second data signal Data2 correspond to the same gamma constant, can be applied to the timing controller 400. When only lateral visibility is considered (hereinafter referred to as a lateral reinforcement mode), a selection signal SS, making the first data signal Data1 and the second data signal Data2 correspond to different gamma constants, can be applied to the timing controller 400.

As described above, when receiving the user-initiated selection signal SS, the timing controller 400 supplies first and second data signals Data1 and Data2 that have the same gamma constant. For instance, when the user sends the selection signal SS to the timing controller 400 using a remote controller or the like, the timing controller 400 provides the first data signal Data1 and the second data signal Data2 adapted to the ordinary mode or the lateral reinforcement mode, thereby adjusting the picture quality of the LCD.

As described above, selection of the ordinary mode or the lateral reinforcement mode is controlled by the external selection signal SS; other methods of selection may be implemented. For example, the ordinary mode or the lateral reinforcement mode can be automatically selected according to the kind of external image signal (RGB) sent from the external graphics source. Generally, lateral visibility is taken into greater consideration in a moving image and is less of a factor in a still image. As such, if a still image is to be displayed, the controller 400 uses ordinary mode. However, if moving images are to be displayed, the controller uses lateral reinforcement mode.

The above-described LCD according to an embodiment of the present disclosure can be applied to both a TN (Twisted Nematic) mode LCD, which needs reinforcement of lateral visibility, and a VA mode LCD.

As described above, the LCD according to an embodiment of the present disclosure can effectively improve visibility by applying data signals having different gamma constants to adjacent pixels and by applying data signals having different gamma constants to one pixel in units of a predetermined frame.

In addition, in the LCD according to an embodiment of the present disclosure, separate subpixel groups are not needed, and an aperture ratio can be improved thereby enhancing the entire brightness of the liquid crystal panel 100 and compensating for a variation in the gamma characteristics of the liquid crystal panel 100. Particularly, in a case where the liquid crystal panel is formed of an organic insulating layer, the entire brightness of the liquid crystal panel can be effectively improved.

Those skilled in the art will appreciate that many variations and modifications can be made to embodiments of the present disclosure without substantially departing from the principles of the present invention. Therefore, embodiments of the present disclosure are used in a generic and descriptive sense only and not for purposes of limitation.

1. A liquid crystal display device (LCD) comprising:
a liquid crystal panel having a plurality of gate lines and a plurality of data lines arranged in column and row directions, respectively, and intersecting each other, a plurality of switching elements connected to the plurality of gate lines and the plurality of data lines, and a plurality of pixels connected to the plurality of switching elements;
a gate driver for supplying a gate signal to the gate lines;
a timing controller for receiving an external image signal and producing a first data signal and a second data signal having different gamma constants; and
a data driver for supplying gray voltages corresponding to the first and second data signals produced from the timing controller to a first pixel group of the plurality of pixels and a second pixel group of the plurality of pixels via the data lines.

2. The LCD of claim 1, wherein the first pixel group and the second pixel group are alternately arranged in a matrix pattern.

3. The LCD of claim 2, wherein each of the first pixel group and the second pixel group comprise a single pixel.

4. The LCD of claim 2, wherein each of the first pixel group and the second pixel group comprise red (R), green (G) and blue (B) pixels.

5. The LCD of claim 1, wherein the first data signal corresponds to a first gamma constant γ1, and the second data signal corresponds to a second gamma constant γ2.

6. The LCD of claim 5, wherein an average between the brightness corresponding to a predetermined gray level at the first gamma constant γ1 and the brightness corresponding to a gray level at the second gamma constant γ2 is substantially similar to the brightness corresponding to the predetermined gray level at a normalized gamma constant γnormal.

7. The LCD of claim 5, wherein the first gamma constant γ1 varies on the basis of a critical gray level, which is the maximum gray level at which the brightness becomes substantially zero.

8. The LCD of claim 7, wherein the first gamma constant γ1 has a larger value below the critical gray level than above the critical gray level, and the first gamma constant γ1 is greater than or equal to 3.

9. The LCD of claim 5, wherein the LCD has a resolution of about 58 PPI (Pixels Per Inch) or greater.

10. The LCD of claim 1, wherein the first data signal corresponds to the first gamma constant γ1 in a first period and corresponds to the second gamma constant γ2, which is smaller than the first gamma constant γ1, in a second period, and the second data signal corresponds to the second gamma constant γ2 in the first period and corresponds to the first gamma constant γ1 in the second period.

11. The LCD of claim 10, wherein an average between the brightness corresponding to a predetermined gray level at the first gamma constant γ1 and the brightness corresponding to a gray level at the second gamma constant γ2 is substantially similar to the brightness corresponding to the predetermined gray level at a normalized gamma constant≧normal.

12. The LCD of claim 10, wherein the first period and the second period are the same.

13. The LCD of claim 12, wherein the first period and the second period are both one frame.

14. The LCD of claim 10, wherein the first gamma constant γ1 varies on the basis of a critical gray level, which is the maximum gray level at which the brightness becomes substantially zero.

15. The LCD of claim 14, wherein the first gamma constant γ1 has a larger value below the critical gray level than above the critical gray level, and the first gamma constant γ1 is greater than or equal to 3.

16. The LCD of claim 1, wherein the timing controller contains a first look-up table that converts the external image signal into the first data signal corresponding to the first gamma constant γ1 and a second look-up table that converts the external image signal into the second data signal corresponding to the second gamma constant γ2.

17. The LCD of claim 1, further comprising a memory device containing a first look-up table that converts the external image signal into the first data signal corresponding to the first gamma constant γ1 and a second look-up table that converts the external image signal into the second data signal corresponding to the second gamma constant γ2, and that supplies the first and second look-up tables to the timing controller.

18. A liquid crystal display device (LCD) comprising:
a liquid crystal panel having a plurality of gate lines and a plurality of data lines arranged in column and row directions, respectively, and intersecting each other, a plurality of switching elements connected to the plurality of gate lines and the plurality of data lines, and a plurality of pixels connected to the plurality of switching elements;
a gate driver for supplying a gate signal to the gate lines;
a timing controller for receiving an external image signal and producing a first data signal and a second data signal selectively having different gamma constants or the same gamma constant; and
a data driver for supplying gray voltages corresponding to the first and second data signals produced by the timing controller to a first pixel group of the plurality of pixels and a second pixel group of the plurality of pixels via the data lines.

19. The LCD of claim 18, wherein the first pixel group and the second pixel group are alternately arranged in a matrix pattern.

20. The LCD of claim 19, wherein each of the first pixel group and the second pixel group comprise a single pixel.

21. The LCD of claim 18, wherein each of the first pixel group and the second pixel group comprise red (R), green (G) and blue (B) pixels.

22. The LCD of claim 18, wherein the timing controller determines whether the gamma constants of the first data signal and the second data signal are the same according to an externally produced selection signal.

23. The LCD of claim 18, wherein the first data signal corresponds to a first gamma constant γ1 and the second data signal corresponds to a second gamma constant γ2, and an average between the brightness corresponding to a predetermined gray level at the first gamma constant γ1 and the brightness corresponding to a gray level at the second gamma constant γ2 is substantially similar to the brightness corresponding to the predetermined gray level at a normalized gamma constant γnormal.

24. The LCD of claim 18, wherein the first data signal corresponds to the first gamma constant γ1 in a first period and corresponds to the second gamma constant γ2, which is smaller than the first gamma constant γ1, in a second period, and the second data signal corresponds to the second gamma constant γ2 in the first period and corresponds to the first gamma constant γ1 in the second period.

25. The LCD of claim 24, wherein an average between the brightness corresponding to a predetermined gray level at the first gamma constant γ1 and the brightness corresponding to a gray level at the second gamma constant γ2 is substantially similar to the brightness corresponding to the predetermined gray level at a normalized gamma constant γnormal.

26. The LCD of claim 24, wherein the first period and the second period are both one frame.

27. The LCD of claim 18 wherein the timing controller contains a first look-up table that converts the external image signal into the first data signal corresponding to the first gamma constant γ1 and a second look-up table that converts the external image signal into the second data signal corresponding to the second gamma constant γ2.

28. The LCD of claim 18, further comprising a memory device containing a first look-up table that converts the external image signal into the first data signal corresponding to the first gamma constant γ1 and a second look-up table that converts the external image signal into the second data signal corresponding to the second gamma constant γ2, and that supplies the first and second look-up tables to the timing controller.

29. A method for driving a liquid crystal display device (LCD) comprising a liquid crystal panel having a plurality of gate lines and a plurality of data lines arranged in column and row directions, respectively, and intersecting each other, a plurality of switching elements connected to the plurality of gate lines and the plurality of data lines, and a plurality of pixels connected to the plurality of switching elements, the method comprising:
providing gate signals to the gate lines;
receiving an external image signal and producing a first data signal and a second data signal corresponding to different gamma constants; and
providing gray voltages corresponding to the first data signal and the second data signal to a first pixel group of the plurality of pixels and a second pixel group of the plurality of pixels through the data lines, respectively.

30. The method of claim 29, wherein the first pixel group and the second pixel group are alternately arranged in a matrix pattern.

31. The method of claim 30, wherein each of the first pixel group and the second pixel group comprise a single pixel.

32. The method of claim 30, wherein each of the first pixel group and the second pixel group comprise red (R), green (G) and blue (B) pixels.

33. The method of claim 29, wherein the producing of the first and second data signals comprises converting the external image signals into the first and second data signals corresponding to the first and second gamma constants γ1 and γ2, respectively, and wherein an average between the brightness corresponding to a predetermined gray level at the first gamma constant γ1 and the brightness corresponding to a gray level at the second gamma constant γ2 is substantially similar to the brightness corresponding to the predetermined gray level at a normalized gamma constant γnormal.

34. The method of claim 29, wherein the producing of the first and second data signals comprises converting the external image signal into the first data signal corresponding to the first gamma constant γ1 in a first period and corresponding to the second gamma constant γ2, which is smaller than the first gamma constant γ1, in a second period, and converting the external image signal into the second data signal corresponding to the second gamma constant γ2 in the first period and corresponding to the first gamma constant γ1 in the second period.

35. The method of claim 34, wherein an average between the brightness corresponding to a predetermined gray level at the first gamma constant γ1 and the brightness corresponding to a predetermined gray level at the second gamma constant γ2 is substantially similar to the brightness corresponding to the predetermined gray level at a normalized gamma constant γnormal.

36. The method of claim 34, wherein the first period and the second period are the same.

37. The method of claim 36, wherein the first period and the second period are both one frame.

38. A method for driving a liquid crystal display device (LCD) comprising a liquid crystal panel having a plurality of gate lines and a plurality of data lines arranged in column and row directions, respectively, and intersecting each other, a plurality of switching elements connected to the plurality of gate lines and the plurality of data lines, and a plurality of pixels connected to the plurality of switching elements, the method comprising:
providing gate signals to the gate lines;
receiving an external image signal and producing a first data signal and a second data signal having the same or different gamma constants; and
providing gray voltages corresponding to the first data signal and the second data signal to a first pixel group of the plurality of pixels and a second pixel group of the plurality of pixels through the data lines, respectively.

39. The method of claim 38, wherein the first pixel group and the second pixel group are alternately arranged in a matrix pattern.

40. The method of claim 39, wherein each of the first pixel group and the second pixel group comprise a single pixel.

41. The method of claim 39, wherein each of the first pixel group and the second pixel group comprise red (R), green (G) and blue (B) pixels.

42. The method of claim 38, wherein the producing of the first and second data signals comprises:
receiving an externally produced selection signal; and
producing the first data signal and the second data signal having the same gamma constant.

43. The method of claim 38, wherein when the first and second data signals have different gamma constants, the producing of the first and second data signals comprises converting the external image signals into the first and second data signals corresponding to the first and second gamma constants γ1 and γ2, respectively, and an average between the brightness corresponding to a predetermined gray level at the first gamma constant γ1 and the brightness corresponding to a gray level at the second gamma constant γ2 is substantially similar to the brightness corresponding to the predetermined gray level at a normalized gamma constant γnormal.

44. The method of claim 38, wherein when the first and second data signals have different gamma constants, the producing of the first and second data signals comprises converting the external image signal into the first data signal corresponding to the first gamma constant γ1 in a first period and corresponding to the second gamma constant γ2, which is smaller than the first gamma constant γ1, in a second period, and converting the external image signal into the second data signal corresponding to the second gamma constant γ2 in the first period and corresponding to the first gamma constant γ1 in the second period.

45. The method of claim 44, wherein an average between the brightness corresponding to a predetermined gray level at the first gamma constant γ1 and the brightness corresponding to a gray level at the second gamma constant γ2 is substantially similar to the brightness corresponding to the predetermined gray level at a normalized gamma constant γnormal.

46. The method of claim 44, wherein the first period and the second period are the same.

47. The method of claim 46, wherein the first period and the second period are both one frame.
